(19) United States
(12) Patent Application Publication
(10) Pub. No.: US 2026/0324155 A1
(43) Pub. Date: Oct. 15, 2026

(54) VERTICAL STACKED MICRODISPLAY PANEL WITHOUT COLOR FILTER

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/333,434

(22) Filed: Sep. 19, 2025

(30) Foreign Application Priority Data
Oct. 30, 2024 (KR) 10-2024-0151592
Jan. 21, 2025 (KR) 10-2025-0008957

(51) Int. Cl. H10H 29/34; H10H 29/24; H10H 29/39

(52) U.S. Cl. CPC H10H 29/34; H10H 29/24; H10H 29/39

(57) ABSTRACT

The present invention relates to a vertically stacked microdisplay panel without a color filter which includes a back wafer having a plurality of complementary metal-oxide semiconductor (CMOS) electrode pads aligned on an upper surface, and a plurality of light-emitting diode (LED) stacks each including a plurality of light-emitting portions and a plurality of bonding layers stacked in a vertical direction, and respectively aligned on the plurality of CMOS electrode pads, wherein each of the plurality of LED stacks includes a first light-emitting portion disposed on the CMOS electrode pad and configured to emit a first color, a second light-emitting portion disposed on the first light-emitting portion and configured to emit a second color, and a third light-emitting portion disposed on the second light-emitting portion and configured to emit a third color, each of the plurality of LED stacks emits only a specific color by forming a short passage in at least one of the first light-emitting portion, the second light-emitting portion, and the third light-emitting portion so that a current flows through the light-emitting portion in which the short passage is not formed. According to the present invention, there is an effect of selectively improving the brightness of colors lacking brightness and improving the overall color brightness by connecting light-emitting portions emitting the same color in series.

### CROSS-REFERENCE TO RELATED APPLICATION

This application claims priority to and the benefit of Korean Patent Application No. 10-2025-008957, filed on Jan. 21, 2025, the disclosure of which is incorporated herein by reference in its entirety.

### BACKGROUND

### Field of the Invention

The present invention relates to a vertically stacked microdisplay panel without a color filter, and more particularly, to a vertically stacked light-emitting diode on silicon (LEDOS) microdisplay panel without a color filter that uses an engineering monolithic epitaxy wafer method, thereby eliminating the need for an alignment process of LED stacks and complementary metal-oxide semiconductor (CMOS) electrode pads and allowing each of the LED stacks to emit only a specific color.

### Discussion of Related Art

The types of implementation of the metaverse, which has recently been attracting attention, are classified into four types such as virtual reality (VR), augmented reality (AR), mixed reality (MR), and extended reality (XR). It is expected that the metaverse ecosystem will develop in the future, focusing on XR, which is a reality that combines VR, AR, and MR among the four types. In addition, in order to implement this effectively, devices (for example, smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a conventional microdisplay panel 10 corresponds to a technology that combines a Si CMOS semiconductor wafer process and a high-resolution, high-brightness, ultra-small display process, and the conventional microdisplay panel 10 may have a structure in which a Si CMOS wafer 11 that has a (100) crystal plane of 4″ or more and is provided with a plurality of CMOS electrode pads 12, a plurality of microLED electrode pads 14, and a transparent wafer 13 of 4″ or more that is provided with a plurality of microLED chips 15 are bonded through a conductive bond 16. Meanwhile, the types of microdisplay panels expected to be applied to XR devices include liquid crystal (LC)-based LC on Si (LCOS), organic light-emitting diode (OLED)-based OLED on Si (OLEDOS), and LED on Si (LEDOS) based on ultra-small microLEDs with pixel sizes of less than 5 μm. In addition, in the case of VR where displays with a low pixel density are applied, the microdisplay panels are being developed and mass-produced mainly based on LCOS and OLEDOS.

However, with the advancement of metaverse implementation technology, the need for lightweight AR, MR, and XR devices to which microdisplay panels with a high pixel density are applied is gradually increasing. In addition, although the development of LEDOS technology, which is considered an ideal solution in theory based on its superior inorganic properties, is urgently needed to satisfy these needs, a microdisplay panel platform for this has not yet been established.

LEDOSs based on ultra-small microLEDs with pixel sizes of less than 5 μm have the advantages of an excellent power-to-performance ratio (P/P) and a short response speed when applied to XR devices, and since the LEDoSs are composed of inorganic materials, there are the advantages that the LEDOSs have a long lifespan and have efficient power use to reduce heat generation and enable long-term battery life. Particularly, since XR devices have a very short distance between the display and the eyes, even a slight delay in image conversion can easily cause discomfort such as dizziness. Thus, LEDOS, which has a nanosecond response speed, is considered to be the most suitable for XR devices compared to LCOS and OLEDOS, which have a microsecond response speed.

Furthermore, it is evaluated that the biggest reason why LEDOS is attracting attention in AR, MR, and XR devices, unlike VR, is due to its brightness and luminous efficiency. Since smart glasses can be worn regardless of location, high brightness is essential for normal operation even in outdoor environments such as sunlight. In theory, microLEDs support brightness of tens to millions of nits, and since OLEDs are made of organic materials, whereas microLEDs are made of inorganic materials, the microLEDs also have the advantage of high luminous efficiency.

However, despite the above-described advantages, the biggest reason why LEDOSs based on ultra-small microLEDs with pixel sizes of less than 5 μm have not established as a major component of XR devices is the difficulty in mass production. In other words, LEDOS requires millions of ultra-small microLEDs to be fixed on a Si CMOS wafer so that the process difficulty is high and the yield is very low, which leads to increased manufacturing costs and high component prices. This is reflected in the final consumer price, and it is difficult to satisfy market demand as LEDOS is supplied as a high-priced XR device.

Meanwhile, as shown in FIG. 2, the development of LEDOS to which group III-V compound (GaN, GaP, and the like) microLED light sources are applied has been in progress until recently through traditional approaches such as (1) monolithic integration of wafers (or unit dies) composed of microLED arrays on Si CMOS wafers or (2) hybridization between wafers (or unit dies) on blue, green, and red light source wafers (or unit dies) on which Si CMOS wafers or microLED arrays are fabricated.

One of the biggest obstacles to the development of LEDOS to which blue, green, and red microLED light sources composed of group III-V compounds to date are applied is the difficulty in securing a solution for pixels of less than 5 μm. In addition, recently, 5 μm-level pixels have been successfully demonstrated using monolithic integration technology, and some demonstrators developed based on hybridization technology were fabricated using sapphire flip chips, achieving 10 μm-level pixels. Additionally, it has been demonstrated that it is possible to reduce pixels to the 5 μm level in the same way by using micro tube wiring in hybridization technology. Additionally, it has been demonstrated that it is possible to reduce pixels to the 5 μm level in the same way by using micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer composed of a group III-V compound microLED array and a Si CMOS back plane wafer composed of numerous IC electrode pad arrays, and then assembling them. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDOS to which high-resolution, high-brightness, and high-speed driving blue, green, and red microLED light sources with pixels of less than 5 μm and pitches of less than 3 μm are applied.

Accordingly, a new alternative solution that is capable of overcoming the above-described ultra-fine alignment constraints is required to manufacture LEDOS to which high-resolution, high-brightness, and high-speed operation of blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using conventional engineering monolithic epitaxy wafers using metal bonding, the patterning etching process faces even greater difficulties.

As another example, great progress has been made in solving the problem of limitations in the brightness and resolution of LEDOS to which group III-V compound microLED light sources are recently applied, and a novel engineered monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED fab process in the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in step (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in step (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in step (2), there is a problem that defects occur due to the difficulty in ultra-fine alignment wafer bonding between the Si blanket wafer (that is, front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 ratio.

That is, although the engineering monolithic epitaxy wafer approach presented in the above-described technologies is evaluated to provide a solution that brings us one step closer to the implementation of LEDOS based on ultra-small microLEDs with pixel sizes of less than 5 μm, since there are quality and yield issues caused by the use of metals (low temperature, multi-layer) in wafer bonding, and it is very difficult to manufacture high-resolution microdisplays with ultra-fine pixels of less than 3 μm, and there are also problems with some alignment processes, new alternatives are needed.

In addition, since the conventional vertically stacked tandem structure of the microdisplays still uses a color filter to implement full color, there are disadvantages in terms of color quality, process complexity, and productivity.

Furthermore, when manufacturing a vertically stacked LEDOS microdisplay panel by sequentially forming red, green, and blue light sources on a CMOS Si back wafer, there is a problem that heat treatment is only possible below the heat resistance temperature of the CMOS Si material (typically 300 to 350° C.), which may cause a decrease in bonding strength.

Meanwhile, as the chip size of micro LEDs decreases, there is an issue of a significant reduction in light efficiency and brightness, and this problem is known to be particularly serious in the case of red micro LEDs of the AlGaInP series. In the case of microLEDs for XR devices, the microLEDs have an ultra-small size of 3 μm or less, and commercialization is expected to be difficult in the future due to issues with brightness.

Meanwhile, as the chip size of microLEDs decreases, there is a problem that the light efficiency and brightness decrease significantly, and this problem is known to be more prominent in red microLEDs of the AlGaInP series. MicroLEDs used in XR devices require an ultra-small size of 3 μm or less, and a solution is needed to solve the problem of reduced brightness caused by this.

### RELATED ART DOCUMENT

### Patent Document

(Patent Document 0001) Korea Patent Publication No. 10-2018-0009116

### SUMMARY OF THE INVENTION

The present invention is directed to solving the above-described conventional problems, and providing a vertically stacked light-emitting diode on silicon (LEDOS) microdisplay panel without a color filter by allowing each LED stack to emit only a specific color while eliminating the need for an alignment process of the LED stacks and complementary metal-oxide semiconductor (CMOS) electrode pads by using an engineering monolithic epitaxy wafer method.

According to the present invention, there is provided a vertically stacked microdisplay panel without a color filter that includes a back wafer having a plurality of complementary metal-oxide semiconductor (CMOS) electrode pads aligned on an upper surface, and a plurality of light-emitting diode (LED) stacks each including a plurality of light-emitting portions and a plurality of bonding layers stacked in a vertical direction, and respectively aligned on the plurality of CMOS electrode pads, wherein each of the plurality of LED stacks includes a first light-emitting portion disposed on the CMOS electrode pad and configured to emit a first color, a second light-emitting portion disposed on the first light-emitting portion and configured to emit a second color, and a third light-emitting portion disposed on the second light-emitting portion and configured to emit a third color, and each of the plurality of LED stacks emits only a specific color by forming a short passage in at least one of the first light-emitting portion, the second light-emitting portion, and the third light-emitting portion so that a current flows through the light-emitting portion in which the short passage is not formed.

Also, two or more of at least one of the first light-emitting portion, the second light-emitting portion, and the third light-emitting portion may be stacked.

Furthermore, the plurality of LED stacks may include a first LED stack for emitting only the first color, a second LED stack for emitting only the second color, and a third LED stack for emitting only the third color.

In addition, the first LED stack may emit only the first color by forming the short passage in each of the third light-emitting portion and the second light-emitting portion so that a current flows only through the first light-emitting portion, the second LED stack may emit only the second color by forming the short passage in each of the first light-emitting portion and the third light-emitting portion so that a current flows only through the second light-emitting portion, and the third LED stack may emit only the third color by forming the short passage in each of the first light-emitting portion and the second light-emitting portion so that a current flows only through the third light-emitting portion.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a conventional microdisplay panel;

FIG. 2 shows a conventional light-emitting diode on silicon (LEDOS) development approach;

FIG. 3 shows an approach using a conventional engineering monolithic epitaxy wafer;

FIGS. 4 to 6 are views showing a vertically stacked microdisplay panel without a color filter according to one embodiment of the present invention;

FIG. 7 is a flowchart for describing a method of manufacturing a vertically stacked microdisplay panel without a color filter according to one embodiment of the present invention;

FIGS. 8 and 9 show a process of manufacturing a plurality of front wafers in an n-side up form according to the method of manufacturing a vertically stacked microdisplay panel without a color filter according to one embodiment of the present invention;

FIGS. 10 and 11 shows a process of manufacturing a plurality of front wafers in a p-side up form according to the method of manufacturing a vertically stacked microdisplay panel without a color filter according to one embodiment of the present invention; and

FIGS. 12 to 14 show a process of manufacturing a vertically stacked microdisplay panel according to the method of manufacturing a vertically stacked microdisplay panel without a color filter according to one embodiment of the present invention.

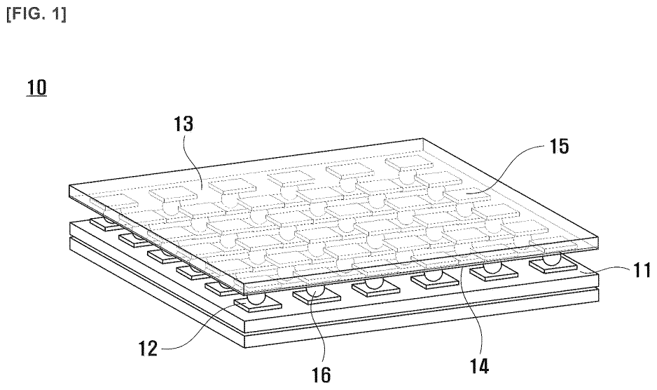

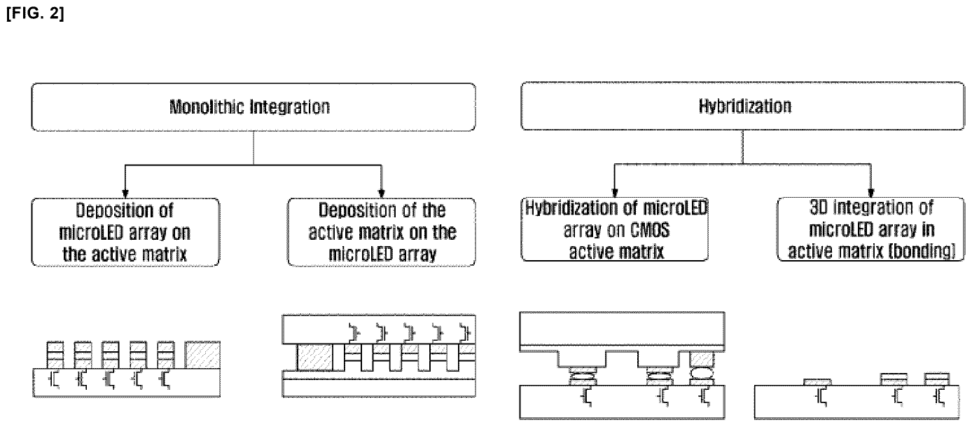

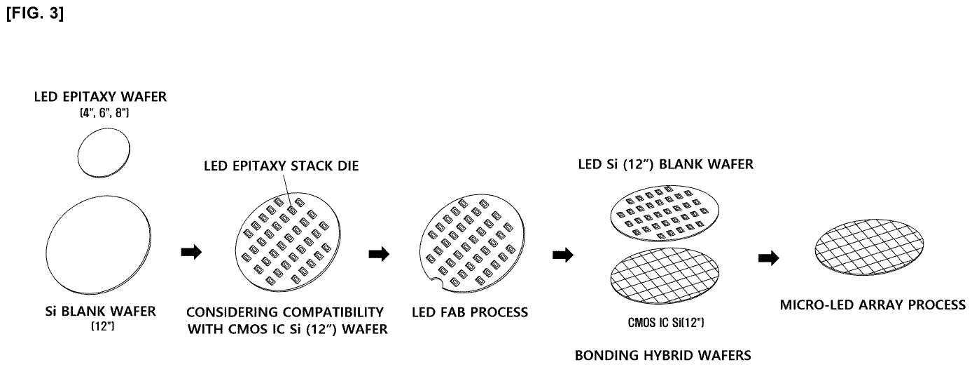

### DETAILED DESCRIPTION OF EXEMPLARY EMBODIMENTS

Hereinafter, some embodiments of the present invention will be described in detail through exemplary drawings. When assigning reference numerals to components of each of the drawings, it should be noted that identical components are denoted by the same reference numerals as much as possible even when they are shown on different drawings.

In addition, when describing embodiments of the present invention, when a detailed description of a related known configuration or function is determined to hinder understanding of the embodiment of the present invention, the detailed description is omitted.

Additionally, when describing components of embodiments of the present invention, terms such as first, second, A, B, (a), (b), and the like may be used. These terms are only intended to distinguish the components from other components, and the nature, order, or sequence of the components are not limited by the terms.

Hereinafter, a vertically stacked microdisplay panel 100 without a color filter according to one embodiment of the present invention will be described in detail with reference to the attached drawings.

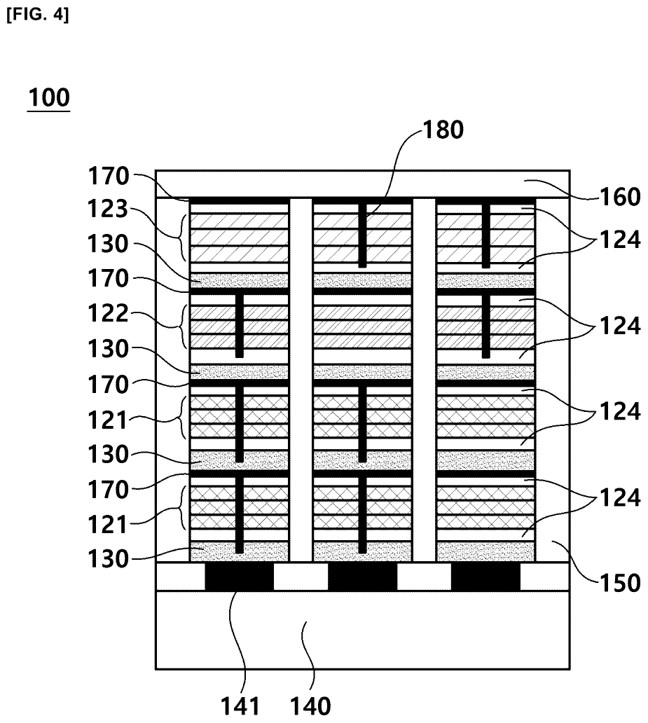

FIGS. 4 to 6 are views showing a vertically stacked microdisplay panel without a color filter according to one embodiment of the present invention.

As shown in FIGS. 4 to 6, the vertically stacked microdisplay panel 100 without a color filter according to one embodiment of the present invention may include a back wafer 140, a plurality of light-emitting diode (LED) stacks 210, 220, 230 a mold portion 150, and a common electrode 160.

The back wafer 140 is an active driving integrated circuit (IC) driven by an active matrix (AM) method and refers to a complementary metal-oxide semiconductor (CMOS) wafer in which a plurality of CMOS electrode pads 141 are arranged on an upper surface in an array. A passivation layer may be formed on the upper surface of the back wafer 140 so that upper surfaces of the plurality of CMOS electrode pads 141 are not exposed, and a portion of the passivation layer may be etched so that the plurality of CMOS electrode pads 141 are exposed when a front wafer is bonded.

Here, the back wafer 140 may be prepared as a Si wafer having a (100) crystal plane and may be prepared as an 8-inch or 12-inch Si wafer according to a standard CMOS IC process. However, considering that a typical LED wafer (front wafer) for bonding is 4 inches or 6 inches, the size of the back wafer 140 is not particularly limited.

The plurality of LED stacks 210, 220, 230 may be respectively aligned on the plurality of CMOS electrode pads 141 and may each include a plurality of light-emitting portions 120 and a plurality of bonding layers 130 stacked in a vertical direction.

Each of the light-emitting portions 120 generates light and may emit blue light, green light, or red light. In the present invention, when the light-emitting portion 120 emits blue light or green light, binary, ternary, or quaternary compounds such as InN, InGaN, GaN, AlGaN, AlN, and AlGaInN, which are group III (Al, Ga, and In) nitride semiconductors among group III-V compound semiconductors, may be disposed in an appropriate position and order on an initial growth wafer G and epitaxially grown.

Particularly, in order to emit blue or green light, a high-quality group III nitride semiconductor such as InGaN with a high In composition needs to be preferentially formed on an upper portion of a group III nitride semiconductor composed of GaN, AlGaN, AlN, or AlGaInN, but is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are group III (Al, Ga, and In) phosphide semiconductors among group III-V compound semiconductors, may be disposed in an appropriate position and order on the initial growth wafer G and epitaxially grown. In addition, in recent years, in order to further improve the development of device and process technology and the value of display panel products, in the case of emitting red light, a high-quality group III nitride semiconductor such as InGaN with a high In composition of 30% or more, other than the group III phosphide semiconductor, may be preferentially formed on an upper portion of a group III nitride semiconductor composed of GaN, AlGaN, AlN, or AlGaInN.

Particularly, in order to emit red light, a high-quality group III phosphide semiconductor such as InGaP having a high In composition needs to be preferentially formed on an upper portion of a group III phosphide semiconductor composed of GaP, AlInP, AlGaP, AlP, or AlGaInP, but is not limited thereto, and for convenience of description, the group III nitride semiconductor is used as a basis for the description below.

More specifically, each of the light-emitting portions 120 may include a first semiconductor region 1201 (for example, a p-type or n-type), an active region 1203 (for example, multi quantum wells, MQWs), and a second semiconductor region 1202 (for example, an n-type when the first semiconductor region 1201 is a p-type or a p-type when the first semiconductor region is an n-type), have a structure in which the second semiconductor region 1202, the active region 1203, and the first semiconductor region 1201 are sequentially epitaxially grown on the initial growth wafer G, and ultimately have a typical thickness of about 5.0 to 8.0 μm overall by including a plurality of multi-layers of group III nitrides, but is not limited to. Hereinafter, the description is based on a case where the first semiconductor region 1201 is a p-type and the second semiconductor region 1202 is an n-type.

The second semiconductor region 1202 may have a second conductivity (for example, an n-type) and may be formed on the growth wafer G. The second semiconductor region 1202 may have a thickness of 2.0 to 3.5 μm and have a nitrogen polarity (N-polarity) surface.

The active region 1203 may generate light by utilizing the recombination of electrons and holes and may be formed on the second semiconductor region 1202. The active region 1203 may have a thickness of several tens of nm in a plurality of layers.

The first semiconductor region 1201 may have a first conductivity (for example, a p-type) and may be formed on the active region 1203. The first semiconductor region 1201 may have a thickness of several tens of nm to several μm in a plurality of layers, and an upper surface thereof may have gallium polarity (Ga-polarity).

That is, the active region 1203 may be disposed between the first semiconductor region 1201 and the second semiconductor region 1202, and when holes in the first semiconductor region 1201, which is a p-type semiconductor region, and electrons in the second semiconductor region 1202, which is an n-type semiconductor region, recombine in the active region 1203, light may be generated.

The plurality of LED stacks 210, 220, 230 may include a first LED stack 210 for emitting only a first color, a second LED stack 220 for emitting only a second color, and a third LED stack 230 for emitting only a third color.

In addition, in the present invention, each of the first LED stack 210, the second LED stack 220, and the third LED stack 230 may have a tandem structure in which a plurality of light-emitting portions 120 and bonding layers 130 are vertically stacked, and more specifically, may include at least one first light-emitting portion 121 bonded to the CMOS electrode pad 141 through the bonding layer 130 and emitting a first color, at least one second light-emitting portion 122 bonded to the first light-emitting portion 121 through the bonding layer 130 and emitting a second color, and at least one third light-emitting portion 123 bonded to the second light-emitting portion 122 through the bonding layer 130 and emitting a third color.

In this case, in the present invention, considering the wavelength of light, it is preferable that the first color of the first light-emitting portion 121 of a lower layer be red with a long wavelength, the second color of the second light-emitting portion 122 of a middle layer be green, and the third color of the third light-emitting portion 123 of an upper layer be blue with a short wavelength, but the present invention is not limited thereto.

Meanwhile, in the present invention, the brightness of the corresponding color can be significantly improved by stacking two or more of at least one of the first light-emitting portion 121, the second light-emitting portion 122, and the third light-emitting portion 123 and connecting the first light-emitting portions 121, the second light-emitting portions 122, and the third light-emitting portions 123 in series.

For example, as shown in FIG. 4, the brightness of red can be greatly improved by configuring only two first light-emitting portions 121 and connecting the first light-emitting portions 121 in series. In addition, although the first light-emitting portion 121 that emits red is used as an example in the above example, the same method can be applied to the second light-emitting portion 122 that emits green or the third light-emitting portion 123 that emits blue.

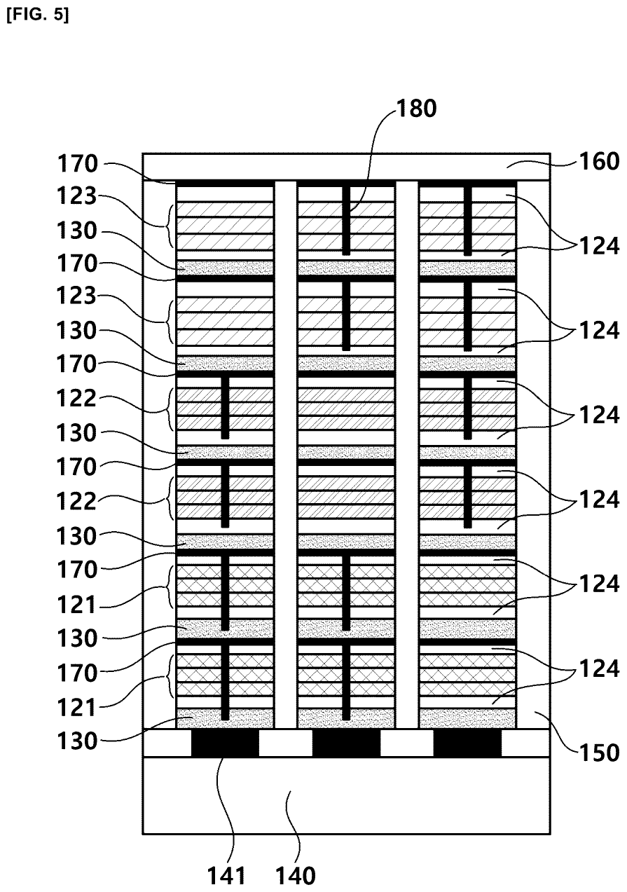

Furthermore, as shown in FIG. 5, the overall color brightness can be significantly improved by configuring two first light-emitting portions 121, two second light-emitting portions 122, and two third light-emitting portions 123 and connecting the first light-emitting portions 121, the second light-emitting portions 122, and the third light-emitting portions 123 in series, but the number of light-emitting portions 120 is not limited to the above-described examples, and three or more light-emitting portions 120 emitting the same color may be connected in series as needed. However, in this case, a thickness of the micro LED chip die needs to be taken into consideration.

Accordingly, the brightness can be selectively improved for colors with insufficient brightness by connecting light-emitting portions 120 that emit the same color in series, and there is an effect of improving the overall color brightness.

In addition, in the present invention, each light-emitting portion 120 may be stacked in an n-side up form in which an n-type semiconductor region is disposed on top, or in a p-side up form in which a p-type semiconductor region is disposed on top.

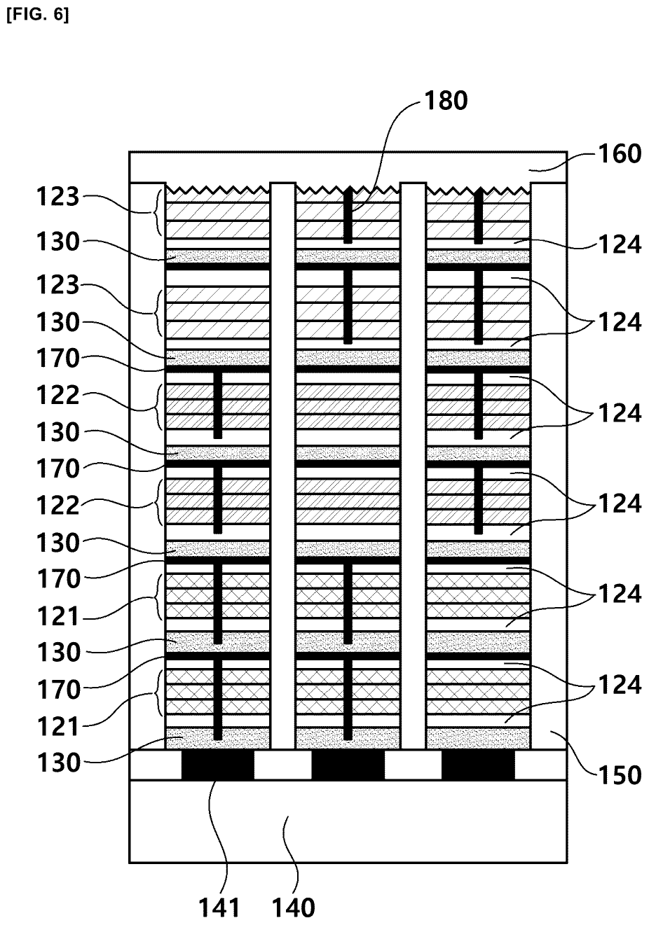

In this case, as shown in FIG. 6, in the present invention, surface texturing may be performed on the surface of the uppermost light-emitting portion 120 to increase light-emitting efficiency. In this case, it is preferable to have the light-emitting portions 120 stacked in an n-side up form to facilitate surface texturing, thereby allowing the surface of the uppermost light-emitting portion 120 to have nitrogen polarity, but the present invention is not limited thereto.

In addition, an ohmic contact electrode 124 that is electrically connected to the light-emitting portion 120 through ohmic contact may be formed on at least one of the upper and lower surfaces of each of the first light-emitting portion 121, the second light-emitting portion 122, and the third light-emitting portion 123.

The ohmic contact electrode 124 may be formed of a material having transparent conductivity. In addition, the material of the ohmic contact electrode 124 that is formed to be in contact with the first semiconductor region 1201, which is a p-type semiconductor, may include NiO, PtO, PdO, AgO2, Au, Rh2O3, RuO2, In2O3, SnO2, ZnO, IZO, ITO, and/or IGZO. The material of the ohmic contact electrode 124 that is formed to be in contact with the second semiconductor region 1202, which is an n-type semiconductor, may include TiN, CrN, VN, In2O3, SnO2, ZnO, IZO, ITO, and/or IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a chemical mechanical polishing (CMP) process to polish and planarize the surface of the second semiconductor region 1202 before forming the ohmic contact electrode 124 having transparent conductivity.

Additionally, the surface of the ohmic contact electrode 124 may also be polished and smoothed through mechanical polishing (MP) or chemical-mechanical polishing (CMP).

Also, the bonding layer 130 may be formed of a ceramic material that is optically transparent and electrically conductive, that is, has transparent conductivity. Here, optically transparent means transparent (a transmittance of 80% or more) or translucent (semitransparent with a transmittance of 50% or more) within the wavelength range of light (including visible light) used in an optical exposure (photolithography) process, and electrically conductive means having an electrical resistance of less than 10-3 Ω/cm. The ceramic materials having transparent conductivity may include a transparent conductive oxide (TCO), a transparent conductive nitride (TCN), and/or a transparent conductive oxide nitride (TCON).

In this case, when the ceramic material is a transparent conductive oxide, the ceramic material may include In2O3, SnO2, ZnO, IZO, ITO, and IGZO, when the ceramic material is a transparent conductive nitride, the ceramic material may include TiN, CrN, and VN, and when the ceramic material is a transparent conductive oxide nitride, the ceramic material may include InON, SnON, ZnON, IZON, ITON, and IGZON.

In the present invention, each of the plurality of LED stacks 210, 220, 230 may emit only a specific color without a color filter by forming a short passage 180 in at least one of the plurality of light-emitting portions 120 so that a current can flow to the light-emitting portion 120 in which the short passage 180 is not formed. In other words, each of the plurality of LED stacks 210, 220, 230 of the present invention may emit only a specific color by diverting a current to a light-emitting portion 120 where the short passage 180 is not formed so that a current is not injected into a light-emitting portion 120 where the short passage 180 is formed.

More specifically, among the plurality of LED stacks 210, 220, 230, the first LED stack 210 of the present invention may emit only the first color by forming the short passage 180 in each of the third light-emitting portion 123 and the second light-emitting portion 122 so that a current can flow only to the first light-emitting portion 121. In this case, an upper side of the short passage 180 may be electrically connected to the common electrode 160 through a transmissive layer 170.

In addition, the second LED stack 220 may emit only the second color by forming the short passage 180 in each of the third light-emitting portion 123 and the first light-emitting portion 121 so that a current can flow only through the second light-emitting portion 122. In this case, an upper side of the short passage 180 may be electrically connected to a third bonding layer 133 through the transmissive layer 170.

In addition, the third LED stack 230 may emit only the third color by forming the short passage 180 in each of the second light-emitting portion 122 and the first light-emitting portion 121 so that a current can flow only through the third light-emitting portion 123. In this case, an upper side of the short passage 180 may be electrically connected to a second bonding layer 132 through the transmissive layer 170.

Meanwhile, in the present invention, after forming a through hole to form the short passage 180, the through hole may be filled with an optically transparent and electrically conductive material, and after filling the through hole, the material may remain on the surface of the light-emitting portion 120 or may be removed. In this case, when the material remains on the light-emitting portion 120, the transmissive layer 170 may be formed.

Here, forming the short passage 180 after forming the through hole may be performed by filling the through hole in a direct self-align manner or by filling the through hole in a liquid coating manner such as solgel, but the present invention is not limited thereto, and any method may be used to form the short passage 180 in the through hole.

Specifically, after the short passage 180 is formed in the first light-emitting portion 121, the transmissive layer 170 electrically connected to the short passage 180 may be formed, after the short passage 180 is formed in the second light-emitting portion 122, the transmissive layer 170 electrically connected to the short passage 180 may be formed, and after the short passage 180 is formed in the third light-emitting portion 123, the transmissive layer 170 electrically connected to the short passage 180 may be formed. In this case, both the short passage 180 and the transmissive layer 170 may be formed of an optically transparent and electrically conductive material.

Meanwhile, in the present invention, the through hole may be filled with a non-transparent conductive material to form the short passage 180. In this case, after filling the through hole, the material needs to be removed so that the material does not remain on the surface of the bonding layer 130 on the light-emitting portion 120, and the transmissive layer 170 may be formed of a separate material that is optically transparent and electrically conductive.

The above-described short passage 180 may be formed of an optically transparent and electrically conductive material or a non-transparent metallic material. When the short passage 180 is formed of an optically transparent and electrically conductive material, it is preferable to form the short passage 180 using a material having low resistance and high transmittance characteristics. These materials may include, but are not limited to, In2O3, SnO2, ZnO, IZO, ITO, and IGZO. Additionally, when the short passage 180 is formed of a metallic material, the short passage 180 may include, but is not limited to, Ag, Cu, Au, Pd, Pt, Ni, Mo W, and electrically conducting nanoparticles.

Additionally, the transmissive layer 170 may also be formed of an optically transparent and electrically conductive material, and it is preferable to form the transmissive layer 170 using a material having the same low resistance and high transmittance characteristics. These materials may include, but are not limited to, In2O3, SnO2, ZnO, IZO, ITO, and IGZO.

In the present invention, the plurality of LED stacks 210, 220, 230 respectively disposed and aligned on the plurality of CMOS electrode pads 141 are separated into preset units. Here, the preset unit means a pixel or sub-pixel unit, and may mean the diameter (width) of each of the plurality of LED stacks 210, 220, 230.

In addition, as shown in FIGS. 4 to 6, in the present invention, although the light-emitting areas of the plurality of LED stacks 210, 220, 230 may all be the same, an operating voltage may be set differently or the same for each LED stack 210, 220, 230.

Typically, each light-emitting portion 120 that emits red, green or blue does not have the same operating voltage. However, assuming that the operating voltage of each light-emitting portion 120 is 3 V, when two first light-emitting portions 121 emitting red light are configured and connected in series as shown in FIG. 4, the operating voltage of the first LED stack 210 emitting red light may be set to 6 V, and the operating voltages of the second LED stack 220 and the third LED stack 230 emitting green and blue light may each be set to 3 V. In addition, as shown in FIG. 5, when two first light-emitting portions 121, two second light-emitting portions 122, and two third light-emitting portions 123 are provided and connected in series, the operating voltages thereof may all be set to 6 V.

That is, although the present invention has a stacked structure, the serial connection between the light-emitting portions 120 that emit different colors is released by flowing electricity through the short passage 180.

The mold portion 150 may support a vertically stacked LEDOS structure and may be formed to fill the space between the plurality of aligned LED stacks 210, 220, 230.

The common electrode 160 may be formed on the plurality of LED stacks 210, 220, 230 on which the mold portion 150 is formed, and the common electrode 160 may be formed of a material having transparent conductivity similar to the ohmic contact electrode 124, when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO. Meanwhile, when the light-emitting portions 120 are stacked in an n-side up form for surface texturing, the common electrode 160 may be provided as a negative electrode.

Additionally, the surface of the common electrode 160 may also be polished to a smooth flat surface through mechanical polishing (MP) or chemical-mechanical polishing (CMP).

Furthermore, although not shown, a coating layer made of a transparent organic material may be additionally formed to protect the common electrode 160 from the atmospheric environment.

Hereinafter, a method S100 of manufacturing a vertically stacked microdisplay panel without a color filter according to one embodiment of the present invention will be described in detail with reference to the attached drawings.

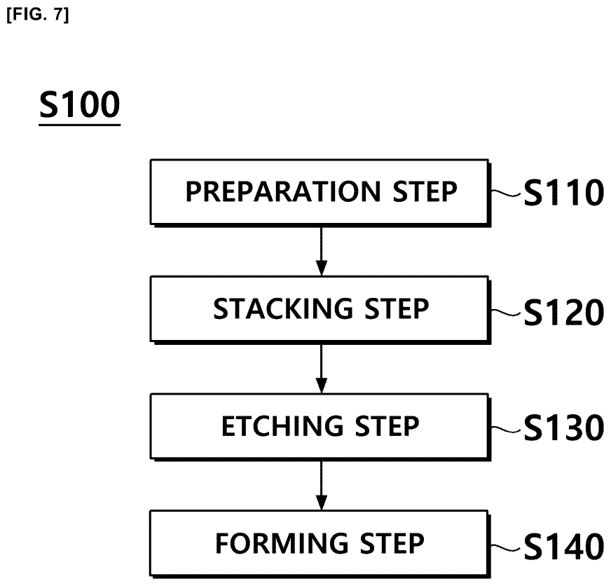

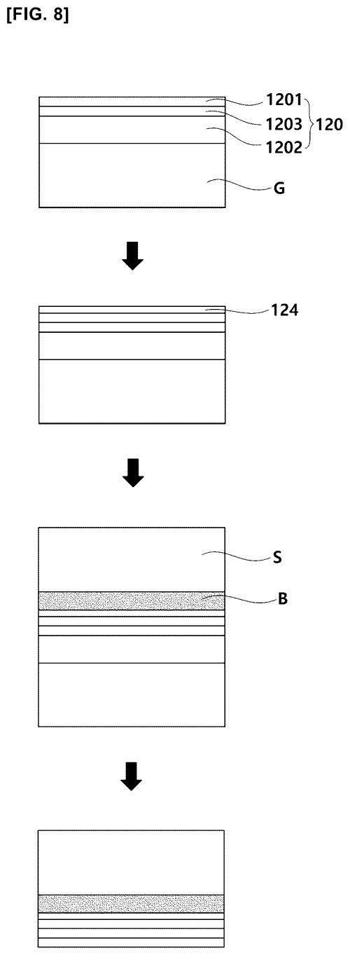

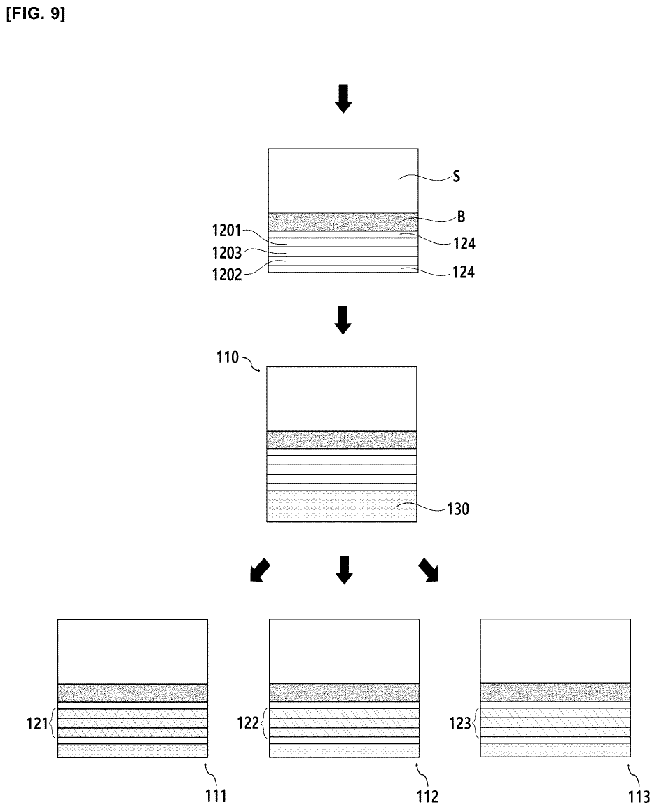

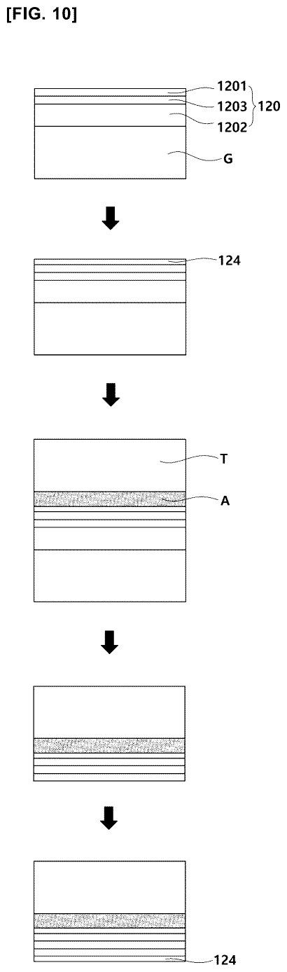

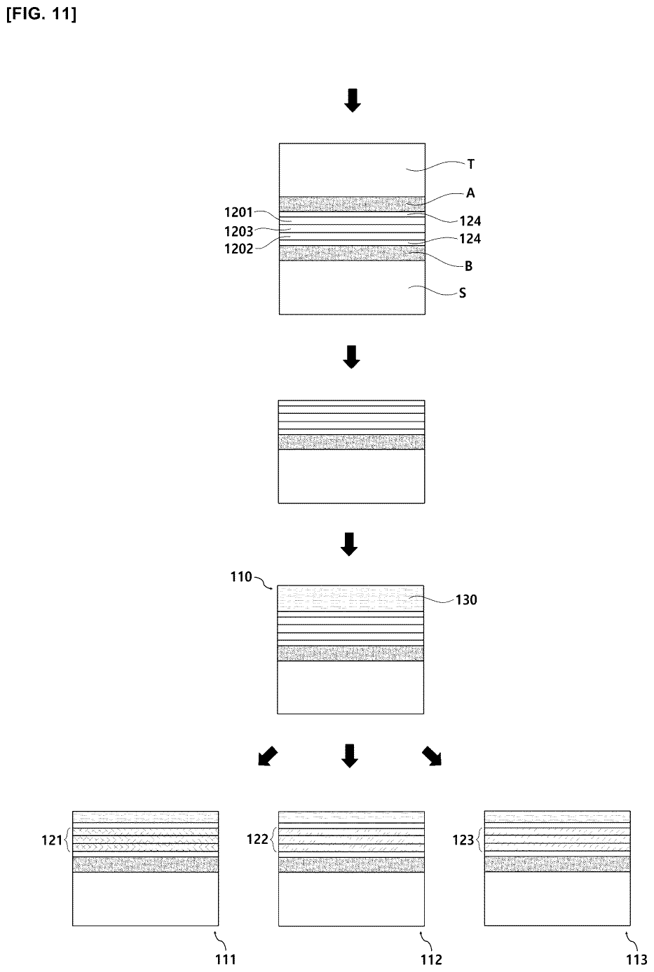

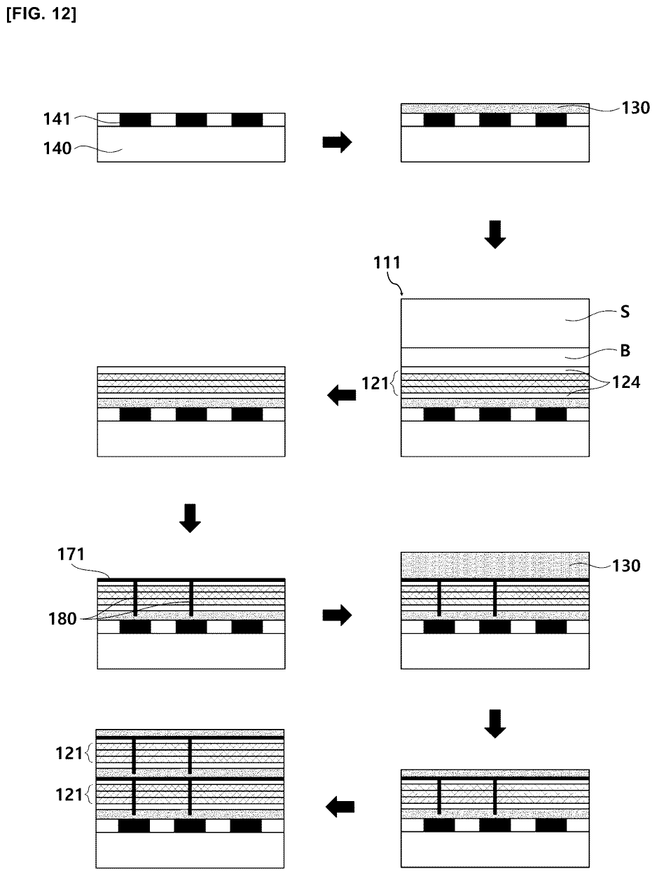

FIG. 7 is a flowchart for describing the method of manufacturing a vertically stacked microdisplay panel without a color filter according to one embodiment of the present invention, FIGS. 8 and 9 show a process of manufacturing a plurality of front wafers in an n-side up form according to the method of manufacturing a vertically stacked microdisplay panel without a color filter according to one embodiment of the present invention, FIGS. 10 and 11 shows a process of manufacturing a plurality of front wafers in a p-side up form according to the method of manufacturing a vertically stacked microdisplay panel without a color filter according to one embodiment of the present invention, and FIGS. 12 to 14 show a process of manufacturing a vertically stacked microdisplay panel according to the method of manufacturing a vertically stacked microdisplay panel without a color filter according to one embodiment of the present invention.

As shown in FIG. 7, the method S100 of manufacturing a vertically stacked microdisplay panel without a color filter according to one embodiment of the present invention may include a preparation step S110, a stacking step S120, an etching step S130, and a forming step S140.

Meanwhile, since the contents not described below are the same as the vertically stacked microdisplay panel 100 without a color filter according to the above-described embodiment of the present invention, a duplicate description is omitted.

The preparation step S110 is a step of preparing a plurality of front wafers 110, a back wafer 140, and a temporary wafer T.

The plurality of front wafers 110 are each for emitting different colors, and the plurality of front wafers 110 may include a first front wafer 111 for emitting a first color, a second front wafer 112 for emitting a second color different from the first color, and a third front wafer 113 for emitting a third color different from the first and second colors. Meanwhile, the first color, the second color, and the third color may be, for example, red, green, and blue, respectively, but are not limited thereto, and may include various other colors.

Here, more specifically, the plurality of front wafers 110 may include a first front wafer 111 including a support wafer S and a first light-emitting portion 121 disposed on an upper portion of the support wafer S, a second front wafer 112 including the support wafer S and a second light-emitting portion 122 disposed on an upper portion of the support wafer S, and a third front wafer 113 including the support wafer S and a third light-emitting portion 123 disposed on an upper portion of the support wafer S.

In the present invention, although the materials of the growth wafer G, temporary wafer T and/or support wafer S may each be silicon (Si) or sapphire, the selection of the material may be determined according to a wafer bonding method.

Meanwhile, as shown in FIGS. 8 and 9, the front wafers 110 of the present invention may each be manufactured in an n-side up form in which the second semiconductor region 1202 having a second conductivity (n-type) is exposed to the outside, or as shown in FIGS. 10 and 11, the front wafers 110 of the present invention may each be manufactured in a p-side up form in which the first semiconductor region 1201 having a first conductivity (p-type) is exposed to the outside.

Accordingly, when the front wafer 110 has an n-side up form, the front wafer 110 may have a structure in which the Si support wafer S having a (111), (110), or (100) crystal plane, the bonding layer B, the ohmic contact electrode 124, the first semiconductor region 1201, the active region 1203, the second semiconductor region 1202, the ohmic contact electrode 124, and the bonding layer 130 are sequentially stacked, and the Si support wafer S may contribute to the stabilization of the quality of the vertically stacked microdisplay panel because there is no difference in thermal expansion coefficient when bonded to the Si back wafer 140 later.

In addition, when the front wafer 110 has a p-side up form, the front wafer 110 may have a structure in which the Si support wafer S having a (111), (110), or (100) crystal plane, the bonding layer B, the ohmic contact electrode 124, the second semiconductor region 1202, the active region 1203, the first semiconductor region 1201, the ohmic contact electrode 124, and the bonding layer 130 are sequentially stacked, and the Si support wafer S may contribute to the stabilization of the quality of the vertically stacked microdisplay panel because there is no difference in thermal expansion coefficient when bonded to the Si back wafer 140 later.

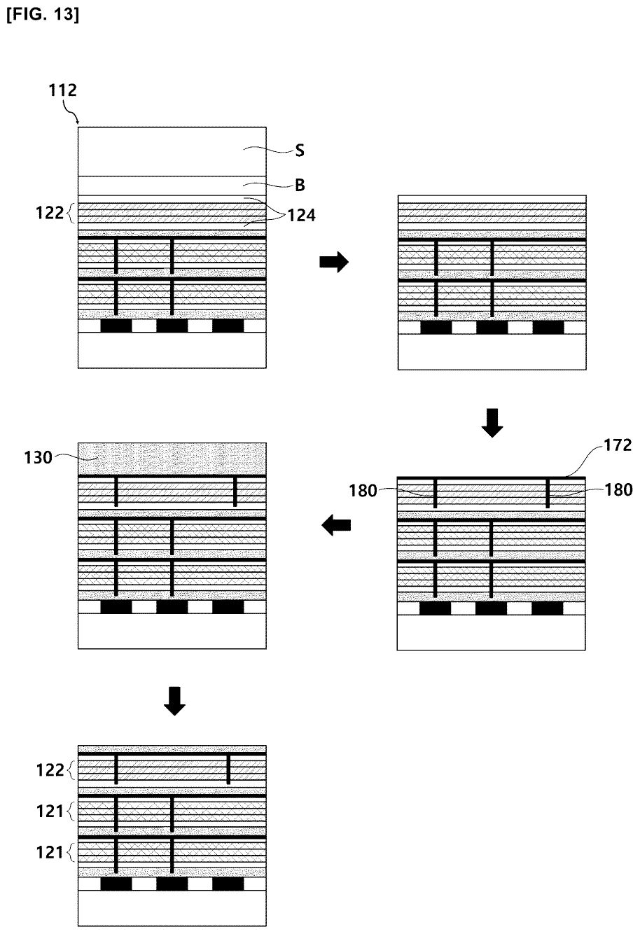

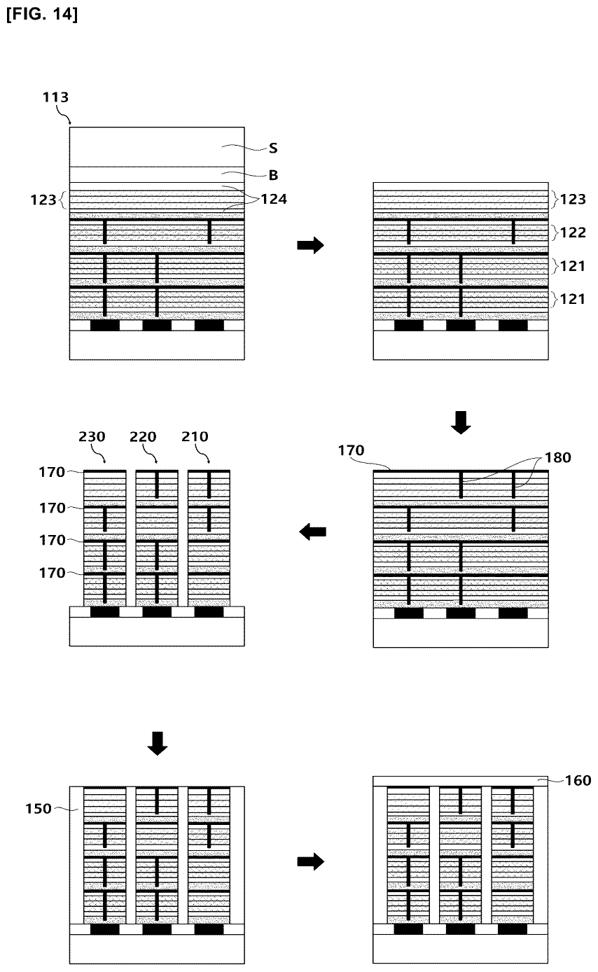

Meanwhile, as shown in FIGS. 13 and 14, when manufacturing a p-side up form, it is of course possible to manufacture a front wafer 110 in a p-side up form by growing the light-emitting portion 120 on the initial growth wafer G and then forming a p-type ohmic contact electrode 124 rather than using two bonding processes through the temporary wafer T. In this case, an n-type ohmic contact electrode 124 may be formed in the second semiconductor region 1202 exposed by removing the initial growth wafer G after the front wafer 110 is bonded to the back wafer 140.

The stacking step S120 is a step of vertically stacking a plurality of light-emitting portions 120 and bonding layers 130 on the back wafer 140 by repeatedly bonding the front wafer 110 with its top and bottom reversed on the back wafer 140 through the bonding layer 130 so that the light-emitting portion 120 of the front wafer 110 faces the CMOS electrode pad 141 side of the back wafer 140, that is, the light-emitting portion 120 of the front wafer 110 and the CMOS electrode pad 141 of the back wafer 140 face each other, and then removing the support wafer S.

In this case, in the present invention, a plurality of at least one of the first front wafer 111, the second front wafer 112, and the third front wafer 113 may be used and stacked so that a plurality of at least one of the first light-emitting portion 121, the second light-emitting portion 122, and the third light-emitting portion 123 are stacked and connected in series.

Additionally, in the stacking step S120, after removing the support wafer S and the bonding layer of the front wafer 110, a short passage may be formed in a portion of the light-emitting portion.

The etching step S130 is a step in which a plurality of stacked light-emitting portions 120 and bonding layers 130 are etched to separate the light-emitting portions 120 and the bonding layers 130 into preset units, thereby allowing the plurality of LED stacks 210, 220, 230 to be respectively disposed and aligned on the plurality of CMOS electrode pads 141. This step eliminates the need for a conventional process of aligning the LED stacks 210, 220, 230 of the front wafer 110 and the CMOS electrode pads 141 of the back wafer 140.

After the etching step S130 described above, among the plurality of LED stacks 210, 220, 230, the first LED stack 210 of the present invention may emit only a first color by forming the short passage 180 in each of the third light-emitting portion 123 and the second light-emitting portion 122 so that a current can flow only through the first light-emitting portion 121. In addition, the second LED stack 220 may emit only a second color by forming the short passage 180 in each of the third light-emitting portion 123 and the first light-emitting portion 121 so that a current can flow only through the second light-emitting portion 122. In addition, the third LED stack 230 may emit only a third color by forming the short passage 180 in each of the second light-emitting portion 122 and the first light-emitting portion 121 so that a current can flow only through the third light-emitting portion 123.

The forming step S140 is a step of forming the mold portion 150 that fills a space between the plurality of aligned LED stacks 210, 220, 230, and then forming the common electrode 160 on the plurality of LED stacks 210, 220, 230.

According to the present invention, since a color filter is unnecessary despite the adoption of a vertically stacked tandem structure, the color quality of a microdisplay can be significantly improved, and process complexity and productivity can be significantly improved.

In addition, according to the present invention, unlike the existing monolithic integration method or hybridization method that has alignment issues, since an engineering monolithic epitaxy wafer is first manufactured, and then the stack on the engineering monolithic epitaxy wafer is etched to separate the stack into preset units so that a plurality of LED stacks are aligned on a plurality of CMOS electrode pads, this has the effect of significantly increasing product yield by enabling the use of not only small-diameter wafers of 6 inches or less, but also large-diameter wafers of 8 inches or more.

In addition, according to the present invention, since a bonding layer and an ohmic contact electrode are made of an electrically conductive transparent ceramic material rather than a metal, the possibility of an electrical short-circuit failure is significantly reduced, and the reliability of the device is greatly increased. In addition, the present invention can have the effect of facilitating etching in a plasma dry process for LED stack alignment and preventing the problem of etching byproducts being redeposited. Moreover, the ease of etching described above can provide a significant advantage in the manufacturing of high-resolution microdisplays having ultra-fine pixels of less than 3 μm.

Furthermore, according to the present invention, a light-emitting portion, a bonding layer, and an ohmic contact electrode are all transparent, allowing visible light to pass through, thereby eliminating alignment errors during an exposure process.

In addition, according to the present invention, there is an effect of selectively improving the brightness of colors lacking brightness and improving the overall color brightness by connecting light-emitting portions emitting the same color in series.

Meanwhile, the effects of the present invention are not limited to the above-described effects, and various other effects may be included within a scope apparent to those skilled in the art from the description below.

Although all components constituting the embodiments of the present invention have been described as being combined or operating in combination as one, the present invention is not necessarily limited to such embodiments. That is, all of the components may be selectively combined and operated in one or more combinations within the scope of the present invention.

Furthermore, terms such as “comprise,” “include,” or “have” described above, unless specifically stated otherwise, imply that the corresponding component may be present, and therefore should be interpreted to include other components rather than excluding other components. All terms, including technical or scientific terms, have the same meaning as commonly understood by a person of ordinary skill in the art to which the present invention pertains, unless otherwise defined. Commonly used terms, such as terms defined in dictionaries, should be interpreted to be consistent with the contextual meaning of the related art, and shall not be interpreted in an ideal or overly formal sense, unless explicitly defined in the present invention.

Further, the above description is merely an example of the technical idea of the present invention, and those skilled in the art will appreciate that various modifications and variations can be made without departing from the essential characteristics of the present invention.

Accordingly, the embodiments disclosed in the present invention are intended to illustrate, rather than limit, the technical concept of the present invention, and the scope of the technical concept of the present invention is not limited by these embodiments. The scope of protection of the present invention should be interpreted by the following claims, and all technical concepts within the scope equivalent thereto should be construed as being included within the scope of the present invention.

What is claimed is:

1. A vertically stacked microdisplay panel without a color filter, comprising:
a back wafer having a plurality of complementary metal-oxide semiconductor (CMOS) electrode pads aligned on an upper surface; and
a plurality of light-emitting diode (LED) stacks each including a plurality of light-emitting portions and a plurality of bonding layers stacked in a vertical direction, and respectively aligned on the plurality of CMOS electrode pads,
wherein each of the plurality of LED stacks includes a first light-emitting portion disposed on the CMOS electrode pad and configured to emit a first color, a second light-emitting portion disposed on the first light-emitting portion and configured to emit a second color, and a third light-emitting portion disposed on the second light-emitting portion and configured to emit a third color, and
each of the plurality of LED stacks emits only a specific color by forming a short passage in at least one of the first light-emitting portion, the second light-emitting portion, and the third light-emitting portion so that a current flows through the light-emitting portion in which the short passage is not formed.

2. The vertically stacked microdisplay panel of claim 1, wherein two or more of at least one of the first light-emitting portion, the second light-emitting portion, and the third light-emitting portion are stacked.

3. The vertically stacked microdisplay panel of claim 2, wherein the plurality of LED stacks include a first LED stack for emitting only the first color, a second LED stack for emitting only the second color, and a third LED stack for emitting only the third color.

4. The vertically stacked microdisplay panel of claim 3, wherein the first LED stack emits only the first color by forming the short passage in each of the third light-emitting portion and the second light-emitting portion so that a current flows only through the first light-emitting portion,
the second LED stack emits only the second color by forming the short passage in each of the first light-emitting portion and the third light-emitting portion so that a current flows only through the second light-emitting portion, and
the third LED stack emits only the third color by forming the short passage in each of the first light-emitting portion and the second light-emitting portion so that a current flows only through the third light-emitting portion.
